(19) United States
(12) Patent Application Publication
(10) Pub. No.: US 2026/0164849 A1
(43) Pub. Date: Jun. 11, 2026

(54) PHOTODETECTOR

(71) Applicant: NTT, Inc., Tokyo (JP)

(72) Inventors: Atsushi Kanda, Musashino-shi, Tokyo (JP); Yasuhiko Nakanishi, Musashino-shi, Tokyo (JP); Koichi Hadama, Musashino-shi, Tokyo (JP); Masahiro Nada, Musashino-shi, Tokyo (JP); Toshihide Yoshimatsu, Musashino-shi, Tokyo (JP)

(21) Appl. No.: 18/716,706

(22) PCT Filed: Dec. 14, 2021
(86) PCT No.: PCT/JP2021/046114

§ 371 Date: Jun. 5, 2024

(51) Int. Cl. H10F 77/00; H10F 39/90

(52) U.S. Cl. CPC H10F 77/933; H10F 39/90

(57) ABSTRACT

A photodetector according to the present disclosure can avoid wire peeling and connection defective, by separating a bonding wire connected to a ground pad of a TIA and a bonding wire connected to a ground potential of a PD sub-mount surface. A photodetector according to the present disclosure includes a substrate, a light-receiving unit installed on the substrate, the light-receiving unit converts an input optical signal into an electric signal, at least one of an anode electrode pad electrically connected to an anode of the light-receiving unit, at least one of a cathode electrode pad electrically connected to a cathode of the light-receiving unit, a ground pad provided on each of both sides of the anode electrode pad and the cathode electrode pad, at least one of a second ground pad installed outside the ground pad; and a wiring pattern electrically connects the ground pad and the second ground pad.

### TECHNICAL FIELD

The present disclosure relates to a photodetector, and more particularly, to a photodetector for high-speed transmission that converts an optical signal into an electrical signal in high-speed optical communication.

### BACKGROUND ART

The transmission rate required for optical communication systems is increasing year by year, and as a transmission rate of optical signals increases, the demand for increase in bandwidth for photodetectors that convert optical signals into electrical signals and optical receiver circuits in which photodetectors are adopted is increasing. In recent years, in addition to a technique for increasing the transmission rate per channel, a technique for increasing the transmission rate by processing a plurality of channel signals in parallel and multiplexing optical signals corresponding to parallelized electric signals by wavelength division or the like has been developed. In addition, with this, there is a growing demand for a technique for receiving multi-channel optical signals by one photodetector and converting them into electric signals all at once by one optical receiver circuit.

In many cases, the optical receiver circuit using the photodetector includes a transimpedance amplifier (hereinafter referred to as TIA) for converting a current signal obtained by the photodetector into a voltage signal and amplifying and outputting the voltage signal, in addition to the photodetector. As the photodetector for high-speed optical communication, a photodiode (hereinafter referred to as PD) is used exclusively. Further, an integration technique for converting a multi-channel optical signal into a multi-channel electric signal by one PD chip, by arranging a plurality of PDs and integrating them on one chip has also been developed. The multi-channel optical receiver circuit using such a PD array chip is configured so that, by using a multi-channel TIA having a plurality of input/output signal terminals, a single TIA chip can convert a multi-channel current signal into a voltage signal and amplify and output the voltage signal (for example, see PTL 1).

FIG. 1 is a diagram conceptually showing the structure of a photodetector 10 for high-speed optical transmission according to the related art, and FIG. 1(a) shows a top view and FIG. 1(b) is a cross-sectional view at a position of a cross-sectional line Ib-Ib. The photodetector 10 is described as a back incident type PD for receiving an optical signal 15 of one channel and outputting an electric signal of one channel. The photodetector 10 includes a substrate 11, a light-receiving unit 12 which is installed on the substrate 11 and receives an optical signal, an anode electrode pad 13 connected to an anode, and a cathode electrode pad 14 connected to the cathode. In the photodetector 10, the optical signal 15 is input from a rear surface (a surface opposite to a surface on which the light-receiving unit 12, the anode electrode pad 13, and the cathode electrode pad 14 are installed) of the substrate 11, and the optical signal 15 is transmitted through the substrate 11 and converted into an electric signal by the light-receiving unit 12. The converted electric signal is output from the anode electrode pad 13 and the cathode electrode pad 14.

FIG. 2 is a diagram conceptually showing the structure of the optical receiver circuit 20 for high-speed transmission according to the related art to which the photodetector 10 is applied, FIG. 2(a) shows a top view, and FIG. 2(b) is a cross-sectional view at the position of the cross-sectional line IIb-IIb. The optical receiver circuit 20 inputs the optical signal 15 of one channel and outputs the electric signal of one channel, similarly to the photodetector 10 shown in FIG. 1. As shown in FIG. 2, the optical receiver circuit 20 includes the photodetector 10, a chip capacitor 21 that is electrically connected to the cathode electrode pad 14 of the photodetector 10 and blocks the leakage of an AC signal converted from light to electricity to the outside, a PD sub-mount 22 whose surface is metallized and on which the photodetector 10 and the chip capacitor 21 are installed on the upper surface, a TIA 23 that converts the current signal converted by the photodetector 10 into a voltage signal and amplifies and outputs the voltage signal, a TIA carrier 24 whose surface is metallized and on which the TIA 23 is installed on the upper surface, and bonding wires (bonding wires 25 and 26, and bonding wires 27a and 27b) for electrically connecting elements. The PD sub-mount 22 further includes a through-hole 221 for receiving the optical signal 15. In addition, the TIA 23 further includes an input signal pad 231 for inputting an electric signal from the photodetector 10, output signal pads 232a and 232b for outputting a differential electric signal to the outside, ground pads 233a to 233e, and a power supply/control/monitor pad 234 for performing supply of power, control and monitoring.

The chip capacitor 21 is a relay terminal for applying a DC voltage from the outside to the cathode electrode pad 14 of the PD 10, and has a function of separating an AC component from a DC component as described above, and blocking leakage of an AC signal to the outside.

A bonding wire 25 electrically connects the anode electrode pad 13 of the photodetector 10 and the input signal pad 231 of the TIA 23. The bonding wire 26 electrically connects the cathode electrode pad 14 of the photodetector 10 and the chip capacitor 21. The bonding wires 27a and 27b electrically connect the ground pad 233 of the TIA 23 and the PD sub-mount 22. Normally, the ground pad 233 of the TIA 23 is electrically connected to the TIA carrier 24 whose surface is metallized via a VIA hole or the like provided in the TIA 23, and is configured to have the same potential (ground potential) as the TIA carrier 24. However, since the VIA hole has a parasitic inductance, the electrical connection with the ground potential by only the VIA hole can be unstable as compared with the ideal ground potential. The bonding wires 27a and 27b also have a function of stabilizing the ground potential of the ground pad 233.

FIG. 3 is a diagram conceptually showing a photodetector 30 for high-speed optical transmission according to the related art, FIG. 3(a) shows a top view, and FIG. 3(b) shows a cross-sectional view at a position of a cross-sectional line IIIb-IIIb. The photodetector 30 is a PD array chip in which a plurality of elements (as an example, four in this case) are arranged on one substrate 11 and integrated into one chip. That is, the photodetector 30 can convert the four-channel optical signals into four-channel electric signals all at once, while being on one PD chip. The PD array chip in which such a plurality of PDs are integrated as one chip has an advantage that the mounting cost can be reduced as compared with a case where the same number of individual PD chips are mounted.

FIG. 4 is a diagram showing a mounting example of an optical receiver circuit 40 for high-speed transmission according to the related art to which the photodetector 30 shown in FIG. 3 is applied, FIG. 4(a) showing a top view, and FIG. 4(b) showing a cross-sectional view at the positions of the IVb-IVb cross-sectional lines. The optical receiver circuit 40 has a configuration in which the photodetector 10 of the optical receiver circuit 20 shown in FIG. 2 is replaced with the photodetector 30. However, since a plurality of optical signals 15 (four channels, for example) are made incident on the rear surface of the photodetector 30, the through-hole 221 is a large hole in which four channels are integrated. The TIA 23 is a multi-channel TIA having four systems of amplifier circuits, and further includes an input signal pad 231, an output signal pad 232, a ground pad 233, and a power supply/control/monitor pad 234 for four channels. The bonding wire 25 electrically connects between each of four anode electrode pads 13 installed in the photodetector 30 and four input signal pads 231 of the TIA 23. The bonding wires 26 electrically connect the four cathode electrode pads 14 installed in the photodetector 30 and the four chip capacitors 21, respectively. The bonding wires 27a and 27b electrically connect the ground pads 233 of the respective amplifier circuits of four systems of the TIA 23 and the PD sub-mount 22.

On the other hand, in recent years, an increase in the transmission rate of the optical communication system has been developed. Accordingly, in the optical receiver circuit according to the related art described above, there was a problem that the impedance increased due to the inductance of the bonding wire (for example, the bonding wire 25) for connecting the anode electrode pad and the input signal pad. This increase in impedance may cause a problem of adversely affecting the frequency characteristics of the optical receiver circuit. As one of the techniques for solving such a problem, a method in which ground pads are installed on both sides of the anode electrode pad and the cathode electrode pad, and the ground pad and the ground pad of the TIA opposite to each other are electrically connected is known.

FIG. 5 is a diagram conceptually showing a photodetector 50 for high-speed optical transmission in which ground pads 51a and 51b and 52a and 52b are installed on both sides of the anode electrode pad 13 and the cathode electrode pad 14, FIG. 5(a) shows a top view, and FIG. 5(b) shows a cross-sectional view at a position of the Vb-Vb cross-sectional line. FIG. 6 is a top view conceptually showing the structure of an optical receiver circuit 60 for high-speed transmission to which the photodetector 50 shown in FIG. 5 is applied. Here, the photodetector 50 and the optical receiver circuit 60 are shown in a configuration in which the optical signal 15 of one channel is input and the electric signal of one channel is output. As shown in FIG. 5, in addition to the configuration of the photodetector 10, the photodetector 50 includes ground pads 51a and 51b and ground pads 52a and 52b installed on both sides of the anode electrode pad 13 and the cathode electrode pad 14 in a longitudinal direction (X direction in the drawing). Further, as shown in FIG. 6, the bonding wires 27a and 27b are configured to electrically connect the ground pads 51a and 51b and the ground pad 233 of the TIA 23 that are opposite to each other. With such a configuration, since the transmission of a signal by the bonding wire 25 is in a coplanar mode, the impedance of the bonding wire 25 can be reduced. Such implementations have similar effects when applied to multi-channel configurations, such as those shown in FIGS. 3 and 4.

However, in the optical receiver circuit 60, there is a problem in instability of ground potential of the ground pads 51a and 51b. Usually, the PD is different from the TIA, and it is difficult to form a VIA hole, side surface metallization, or the like, and the ground pads 51a and 51b are in an electrically floating state. In addition, even if the ground potential of the ground pads 51a and 51b is connected to the ground pad 233 of the TIA 23 via bonding wires 27a and 27b, since there is inductance in the VIA hole or the like of the TIA 23, the TIA 23 becomes unstable compared with an ideal ground potential. From such a viewpoint, in the optical receiver circuit 60, in order to stabilize the ground potential of the ground pads 51a and 51b, it is necessary to further electrically connect the ground pads 51a and 51b and PD sub-mount 22 by bonding wires 61a and 61b. In this case, since two bonding wires 61a and 61b are connected on the ground pads 51a and 51b, the ends of bonding wires 27a and 27b and bonding wires 61a and 61b may overlap on the ground pads 51a and 51b. As a result, there may be a problem that wire peeling, poor connection, and the like occur, and the yield and reliability are lowered.

In the optical receiver circuit 60, the ground pads 52a and 52b are also required to be electrically connected to the PD sub-mount 22. However, since the chip capacitor 21 is disposed in the vicinity of the cathode electrode pad 14 as described above, the bonding wires 62a and 62b for electrically connecting the PD sub-mount 22 from the ground pads 52a and 52b need to have a long wire length not to interfere geometrically with the chip capacitor 21. However, there is also a problem that, when the wire lengths of the bonding wires 62a and 62b become longer, the impedance due to the inductance of the bonding wires 62a and 62b increases, and the ground potential of the ground pads 52a and 52b becomes unstable.

### CITATION LIST

### Patent Literature

[PTL 1] Japanese U.S. Pat. No. 5,296,838

### SUMMARY OF INVENTION

The present disclosure has been made in view of the above-mentioned problems, and an object thereof is to provide a photodetector capable of avoiding wire peeling and poor connection, by separating a bonding wire connected to a ground pad of a TIA and a bonding wire connected to a ground potential on the surface of a PD sub-mount.

Further, for the aforementioned problem, an object of the present disclosure is to provide a photodetector in which a bonding wire for connecting a cathode electrode pad and a PD sub-mount can be connected with a short wire length without interfering with a chip capacitor.

To solve the above problem, the present disclosure discloses photodetector including a substrate, a light-receiving unit installed on the substrate, the light-receiving unit converts an input optical signal into an electric signal, at least one of an anode electrode pad electrically connected to an anode of the light-receiving unit, at least one of a cathode electrode pad electrically connected to a cathode of the light-receiving unit, a ground pad provided on each of both sides of the anode electrode pad and the cathode electrode pad at least one of a second ground pad installed outside the ground pad, and a wiring pattern electrically connects the ground pad and the second ground pad.

### BRIEF DESCRIPTION OF DRAWINGS

FIG. 1 is a diagram conceptually showing a structure of a photodetector 10 for high-speed optical transmission according to the related art, FIG. 1(a) shows a top view, and FIG. 1(b) shows a cross-sectional view at a position of an Ib-Ib cross-sectional line.

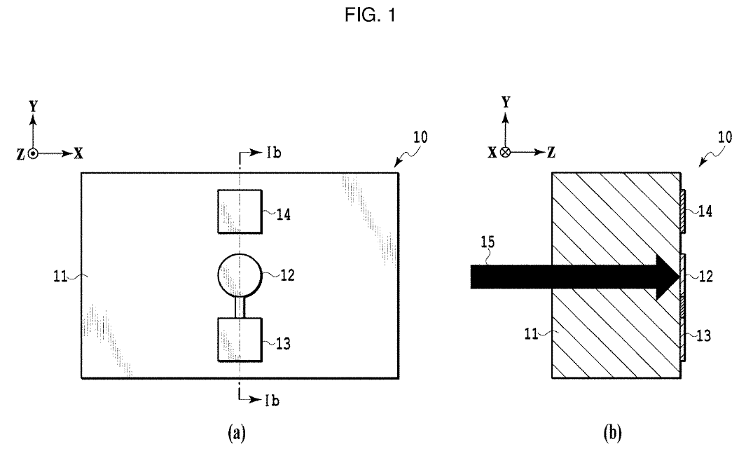

FIG. 2 is a diagram conceptually showing a structure of an optical receiver circuit 20 for high-speed transmission by the related art to which the photodetector 10 is applied, FIG. 2(a) shows a top view, and FIG. 2(b) shows a cross-sectional view at a position of an IIb-IIb cross-sectional line.

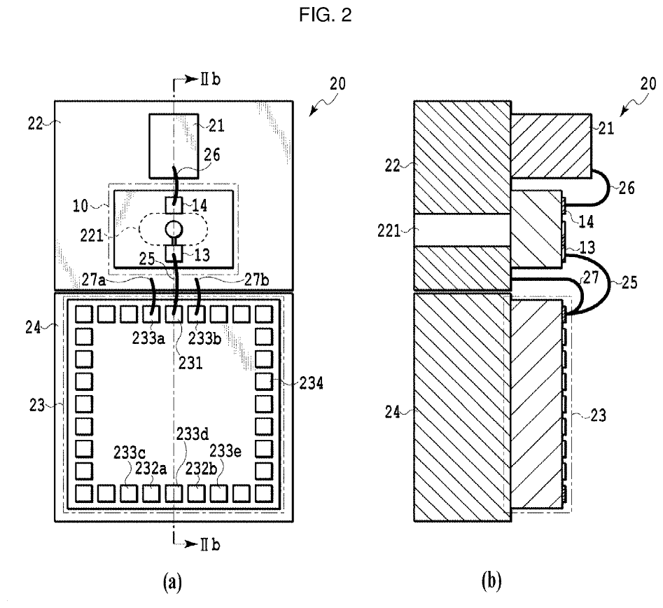

FIG. 3 is a diagram conceptually showing photodetector 30 for high-speed optical transmission according to the related art, FIG. 3(a) shows a top view, and FIG. 3(b) shows a cross-sectional view at a position of a IIIb-IIIb cross-sectional line.

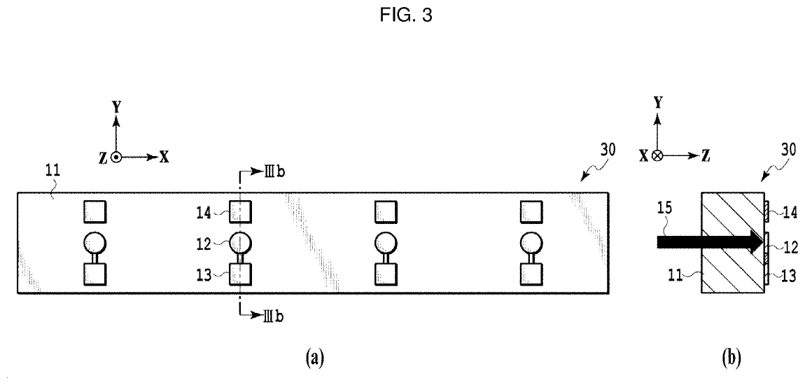

FIG. 4 is a diagram showing a mounting example of an optical receiver circuit 40 for high-speed transmission according to the related art to which the photodetector 30 shown in FIG. 3 is applied, FIG. 4(a) shows a top view, and FIG. 4(b) shows a cross-sectional view at a position of an IVb-IVb cross-sectional line.

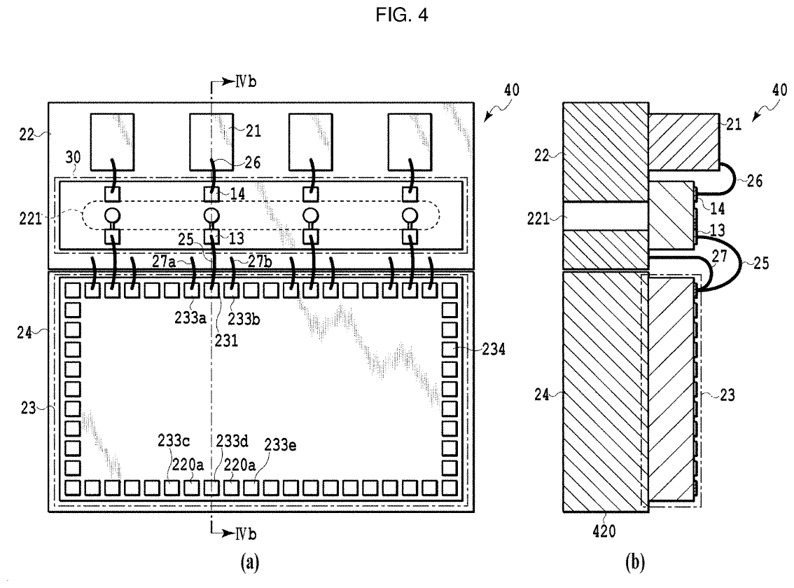

FIG. 5 is a diagram conceptually showing a photodetector 50 for high-speed optical transmission in which ground pads 51a and 51b and 52a and 52b are installed on both sides of the anode electrode pad 13 and the cathode electrode pad 14, FIG. 5(a) shows a top view, and FIG. 5(b) shows a cross-sectional view at a position of a Vb-Vb cross-sectional line.

FIG. 6 is a top view conceptually showing a structure of an optical receiver circuit 60 for high-speed transmission to which the photodetector 50 shown in FIG. 5 is applied.

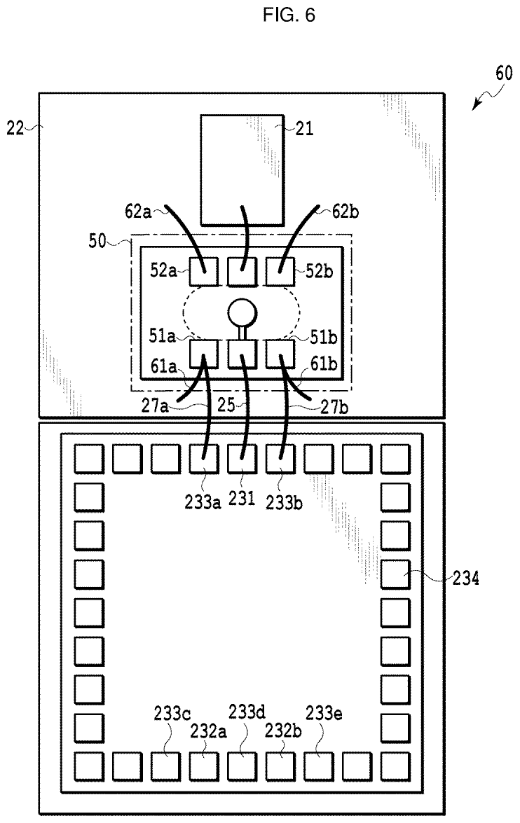

FIG. 7 is a conceptual diagram showing a structure of a photodetector 70 for high-speed transmission according to an embodiment of the present disclosure, FIG. 7(a) shows a top view, and FIG. 7(b) shows a cross-sectional view at a position of a VIIb-VIIb cross-sectional line.

FIG. 8 is a top view conceptually showing a structure of an optical receiver circuit 80 to which a photodetector 70 is applied, according to an embodiment of the present disclosure.

FIG. 9 is a conceptual diagram showing a structure of a photodetector 90 for high-speed transmission according to an embodiment of the present disclosure, FIG. 9(a) shows a top view, and FIG. 9(b) shows a cross-sectional view at a position of an IXb-IXb cross-sectional line.

FIG. 10 is a top view conceptually showing a structure of an optical receiver circuit 100 to which the photodetector 90 is applied, according to an embodiment of the present disclosure.

FIG. 11 is a conceptual diagram showing a structure of a photodetector 110 for high-speed transmission according to an embodiment of the present disclosure, FIG. 11(a) shows a top view, and FIG. 11(b) shows a cross-sectional view at a position of a cross-sectional line XIb-XIb.

FIG. 12 is a top view conceptually showing a structure of an optical receiver circuit 120 to which a photodetector 110 is applied, according to an embodiment of the present disclosure.

### DESCRIPTION OF EMBODIMENTS

Various embodiments of the present disclosure will now be described in detail with reference to the accompanying drawings. The same or similar reference numerals indicate the same or similar elements, and in some cases, redundant descriptions may be omitted. The following description can be implemented with some of the arrangements omitted or modified or with additional arrangements unless departing from the gist of one embodiment of the present disclosure.

### First Embodiment

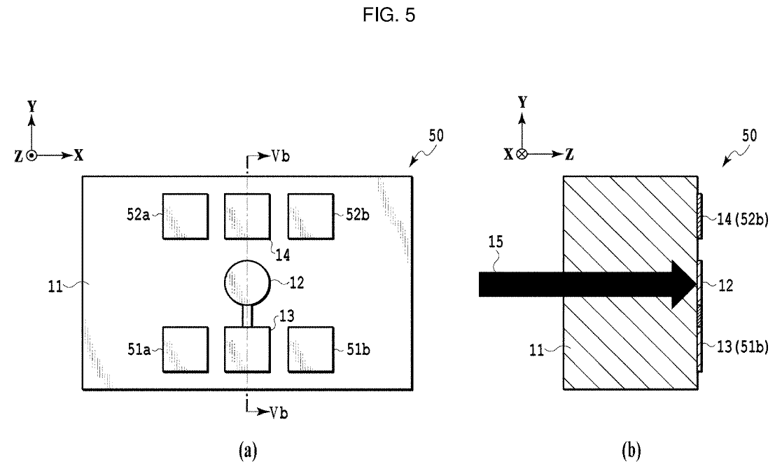

A first embodiment of the present disclosure will now be described in detail with reference to the accompanying drawings. In addition to the structure of the photodetector 50 shown in FIG. 5, the photodetector in this embodiment further includes an additional ground pad for separating the bonding wire connected to the ground pad of the TIA and the bonding wire connected to the ground potential of the PD sub-mount surface. Further, an additional ground pad is installed so that a bonding wire for connecting the cathode electrode pad and the PD sub-mount does not interfere with the chip capacitor.

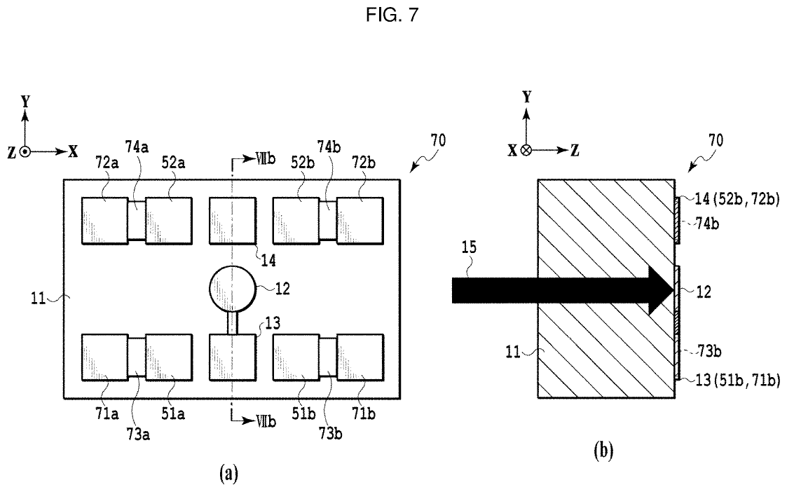

FIG. 7 is a conceptual diagram showing the structure of a photodetector 70 for high-speed transmission according to the first embodiment of the present disclosure, FIG. 7(a) shows a top view, and FIG. 7(b) shows a cross-sectional view at a position of a VIIb-VIIb cross-sectional line. The photodetector 70 is depicted as a back incident type PD similarly to the photodetectors 10, 30 and 50, and includes, in addition to the configuration of the photodetector 50, ground pads 71a and 71b and ground pads 72a and 72b provided outside ground pads 51a and 51b and the ground pads 52a and 52b in the longitudinal direction (X direction in the drawing), wiring patterns 73a and 73b for electrically connecting the ground pads 51a and 51b to the ground pads 71a and 71b, and wiring patterns 74a and 74b for electrically connecting the ground pads 52a and 52b to the ground pads 72a and 72b. Here, the photodetector 70 is shown in a configuration in which the optical signal 15 of one channel is input and an electric signal of one channel is output.

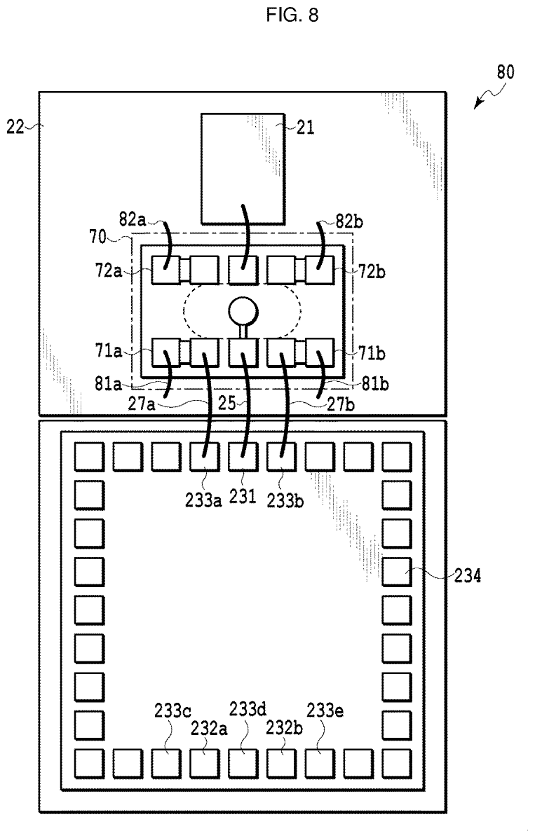

FIG. 8 is a top view conceptually showing the structure of the optical receiver circuit 80 to which the photodetector 70 is applied according to the first embodiment of the present disclosure. A basic configuration of the optical receiver circuit 80 is in the form in which the photodetector 50 in the optical receiver circuit 60 is replaced with the photodetector 70. However, in the optical receiver circuit 60 which is the related art, the ground pads 51a and 51b and the PD sub-mount 22 are electrically connected, but in an optical receiver circuit 80, the newly added ground pads 71a and 71b and the PD sub-mount 22 are electrically connected via bonding wires 81a and 81b. Similarly, in the optical receiver circuit 80, newly added ground pads 72a and 72b and the PD sub-mount 22 are connected via bonding wires 82a and 82b.

In the optical receiver circuit 80 according to the first embodiment of the present disclosure configured in this way, the ground pads 51a and 51b connected to the ground pad 233 of the TIA 23 via the bonding wires 27a and 27b are separated from the ground pads 71a and 71b connected to the PD sub-mount 22 via the bonding wires 81a and 81b. Since the bonding wires 27a and 27b and the bonding wires 81a and 81b are also separated accordingly, the wire peeling, the defective wire connection, the pad peeling, the pad damage, and the like due to the overlapping of the ends of the wires can be avoided, and as a result, the yield and reliability can be improved. Further, the degree of mounting freedom of the bonding wires 61a and 61b increases, the distance between the bonding wires 81a and 81b is shortened as shown in FIG. 8, and the impedance can be reduced.

In addition, with respect to the cathode electrode pad 14 side, it is preferable that the chip capacitor 21 be disposed as close as possible to the cathode electrode pad 14 to reduce the inductance of the bonding wire 26 for connecting the cathode electrode pad 14 and the chip capacitor 21. In the optical receiver circuit 80 according to the first embodiment of the present disclosure, as described above, the ground pads 72a and 72b on the cathode side are also installed separately from the ground pads 52a and 52b, similarly to the ground pads 71a and 71b on the anode side. Therefore, the chip capacitor 21 is not affected by the arrangement of the chip capacitor 21 in the vicinity of the cathode electrode pad 14, and can be connected to the PD sub-mount 22 from the ground pads 72a and 72b. In other words, when the wire lengths of bonding wires 62a and 62b for connecting the ground pads 72a and 72b and the PD sub-mount 22 are made shorter than that of the optical receiver circuit 60 which is the related art, it is possible to lower the impedance and make the ground potential more stable, accordingly.

### Second Embodiment

A second embodiment of the present disclosure will be described in detail below with reference to the accompanying drawings. In this embodiment, the ground pad of the photodetector 50 shown in FIG. 5 has a form that is enlarged in the longitudinal direction.

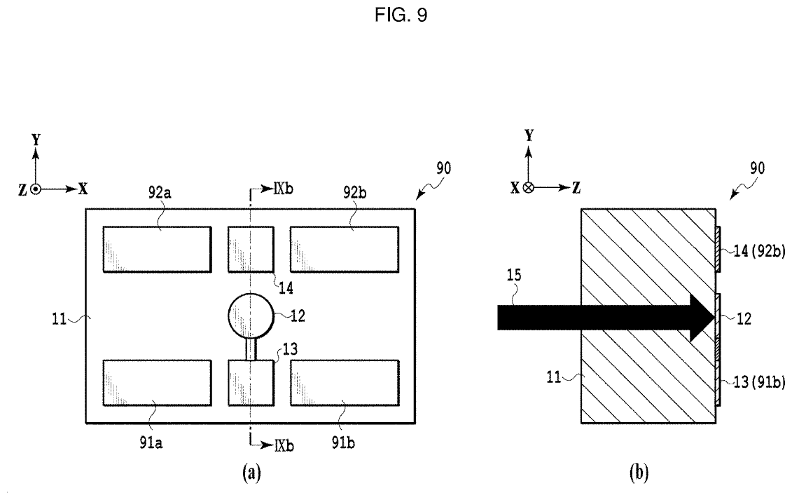

FIG. 9 is a conceptual diagram showing a structure of a photodetector 90 for high-speed transmission according to the second embodiment of the present disclosure, FIG. 9(a) shows a top view, and FIG. 9(b) shows a cross-sectional view at a position of a IXb-IXb cross-sectional line. The photodetector 90 is depicted as a back incident type PD similarly to the photodetectors 10, 30 and 50, and includes, in the configuration of the photodetector 50, ground pads 91a and 91b and ground pads 92a and 92b, as an alternative to the ground pads 51a and 51b and the ground pads 52a and 52b. The ground pads 91a and 91b and the ground pads 92a and 92b have a shape enlarged in the longitudinal direction (X direction in the drawing) as compared with the related art.

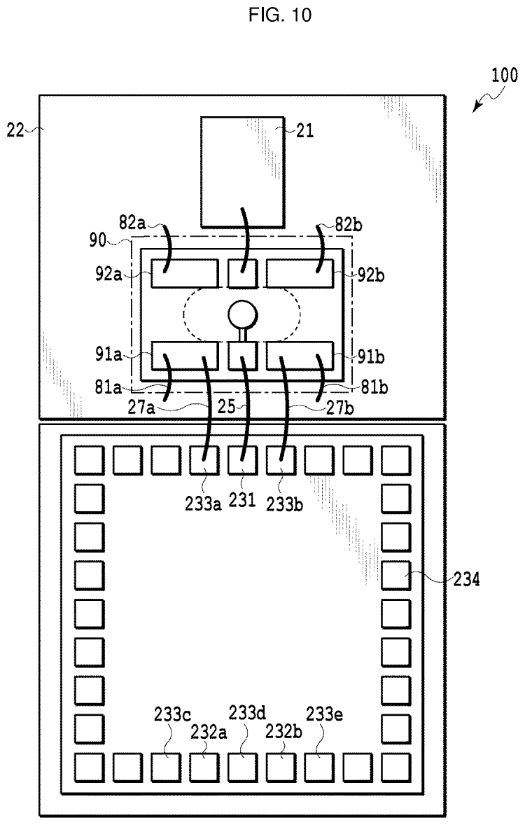

FIG. 10 is a top view conceptually showing the structure of the optical receiver circuit 100 to which the photodetector 90 is applied according to the second embodiment of the present disclosure. The basic configuration of the optical receiver circuit 100 is in a configuration in which the photodetector 50 in the optical receiver circuit 60 is replaced with the photodetector 90.

In the optical receiver circuit 100 having such a configuration, since the ground pads 91a and 91b are expanded in the longitudinal direction (X direction in the drawing), the ends of the bonding wires 27a and 27b and the bonding wires 81a and 81b can be avoided from overlapping. Therefore, the occurrence of wire peeling and connection failure can be prevented, and yield and reliability can be improved. Since the degree of mounting freedom of the bonding wires 81a and 81b increases similarly to the first embodiment, the wire lengths of the bonding wires 81a and 81b are made shorter than that of the related art, and impedance can be reduced.

In addition, as in the first embodiment, on the cathode side, the chip capacitor 21 can also be connected to the PD sub-mount 22 from the ground pads 92a and 92b, without being affected by the fact that the chip capacitor 21 is disposed in the immediate vicinity of the cathode electrode pad 14. In other words, the lengths of bonding wires 82a and 82b for connecting the ground pads 92a and 92b and the PD sub-mount 22 are made shorter than that of the optical receiver circuit 60 which is a related art to reduce the inductance, and the ground potential can be made more stable, accordingly.

In order to achieve the effect of such a configuration, for example, it is necessary for the ground pad 91a to have an effective area for only landing two wires of the bonding wire 27a and the bonding wire 81a, that is, an area in which at least two of the ground pad 51a and the ground pads 71a of FIG. 7 are arranged. Therefore, it is desirable that the lengths of the ground pads 91a and 91b and the ground pads 92a and 92b in the longitudinal direction (X direction in the drawing) be twice or more the respective lengths of the width direction (Y direction in the drawing).

### Third Embodiment

A third embodiment of the present disclosure will be described in detail below with reference to the accompanying drawings. A photodetector according to the present embodiment has a configuration in which ground pads opposite to each other on the anode side and the cathode side are electrically connected by a wiring pattern in the photodetector 70 described in the first embodiment.

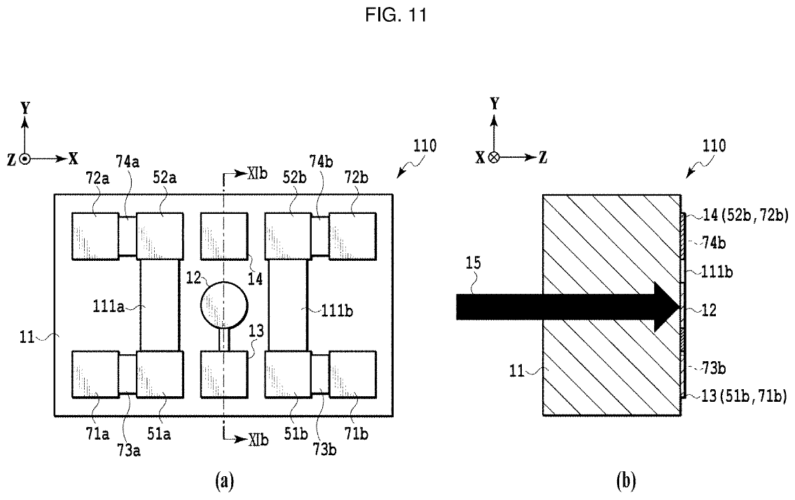

FIG. 11 is a conceptual diagram showing a structure of a photodetector 110 for high-speed transmission according to a third embodiment of the present disclosure, FIG. 11(a) shows a top view, and FIG. 11(b) shows a cross-sectional view at a position of a cross-sectional line XIb-XIb. The photodetector 110 is depicted as a back incident type PD like the photodetectors 10, 30 and 50, and further includes, in addition to the configuration of the photodetector 70, wiring patterns 111a and 111b for electrically connecting ground pads 51a and 51b and the ground pads 52a and 52b that are opposite to each other in the width direction (Y direction in the drawing).

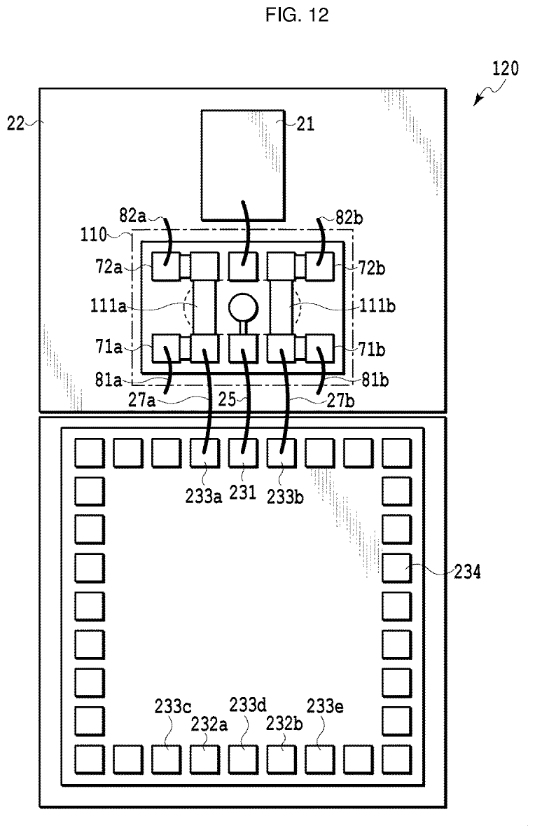

FIG. 12 is a top view conceptually showing a structure of an optical receiver circuit 120 to which the photodetector 110 is applied according to the third embodiment of the present disclosure. The basic configuration of the optical receiver circuit 120 is in the form in which the photodetector 50 in the optical receiver circuit 60 is replaced with the photodetector 110.

In the optical receiver circuit 120 having such a configuration, ground pads 51a and 51b connected to the ground pad 233 of the TIA 23 via the bonding wires 27a and 27b are separated from the ground pads 71a and 71b connected to the PD sub-mount 22 via the bonding wires 81a and 81b. Since the bonding wires 27a and 27b and the bonding wires 81a and 81b are also separated, the wire peeling, the defective wire connection, the pad peeling, the pad damage, and the like due to the overlapping of the ends of the wires can be avoided, and as a result, the yield and reliability can be improved. Further, the degree of mounting freedom of the bonding wires 61a and 61b increases, the distance between the bonding wires 81a and 81b is shortened as shown in FIG. 8, and the impedance can be reduced.

In addition, with respect to the cathode electrode pad 14 side, it is preferable that the chip capacitor 21 be disposed as close as possible to the cathode electrode pad 14 to reduce the inductance of the bonding wire 26 for connecting the cathode electrode pad 14 and the chip capacitor 21. In the optical receiver circuit 80 according to the third embodiment Of the present disclosure, as described above, the ground pads 72a and 72b on the cathode side are also installed separately from the ground pads 52a and 52b in the same way as the ground pads 71a and 71b on the anode side. Therefore, the chip capacitor 21 can be connected to the PD sub-mount 22 from the ground pads 72a and 72b, without being affected by the fact that the chip capacitor 21 is disposed in the immediate vicinity of the cathode electrode pad 14. In other words, the wire lengths of the bonding wires 62a and 62b for connecting the ground pads 72a and 72b and the PD sub-mount 22 are made shorter than that of the optical receiver circuit 60 which is the related art, and the ground potential can be made more stable, accordingly.

Furthermore, in the optical receiver circuit 120, since the ground pads 51a and 51b and the ground pads 52a and 52b are electrically connected to each other by the wiring patterns 111a and 111b, the wiring patterns 111a and 111b act as ground surfaces. Therefore, since a high-frequency electric signal of a photocurrent, generated by receiving the optical signal 15 by the light-receiving unit 12, is transmitted from the light-receiving unit 12 to the input signal pad 231 of the TIA 23 via the anode electrode pad 13 in a coplanar line mode, more excellent frequency characteristics can be obtained.

Although the photodetectors 70, 90 and 110 according to the present disclosure have been described as a configuration in which one channel of the optical signal 15 is input and one channel of the electric signal is output, the number of channels is not limited, and the photodetectors may be of a multi-channel configuration.

Although the photodetectors 70, 90 and 110 are described herein as back incident type PD, the type of PD is not limited thereto, and for example, the same effect can be obtained in the surface incidence type PD and the end surface incidence type PD as long as the configuration includes the anode electrode pad and the cathode electrode pad formed on the upper surface of the element.

### INDUSTRIAL APPLICABILITY

The photodetector according to the present disclosure has an effect capable of avoiding wire peeling and connection defective, by separating the bonding wire connected to the ground pad of the TIA and the bonding wire connected to the ground potential of the PD sub-mount surface. In addition, there is also an effect in which the bonding wire for connecting the cathode electrode pad and the PD sub-mount can be connected with a short wire length without interfering with the chip capacitor. Therefore, it is expected that the photodetector having higher reliability than the related art is applied particularly to an optical receiver circuit for high-speed optical communication.

1. A photodetector comprising:
a substrate;
a light-receiving unit installed on the substrate, the light-receiving unit converting an input optical signal into an electric signal;
at least one of an anode electrode pad electrically connected to an anode of the light-receiving unit;
at least one of a cathode electrode pad electrically connected to a cathode of the light-receiving unit;
a ground pad provided on each of both sides of the anode electrode pad and the cathode electrode pad;
at least one of a second ground pad installed outside the ground pad; and
a wiring pattern electrically connects the ground pad and the second ground pad.

2. The photodetector according to claim 1, further comprising a second wiring pattern, the second wiring pattern electrically connecting the ground pad adjacent to the anode electrode pad and the ground pad adjacent to the cathode electrode pad.

3. A photodetector, comprising:
a substrate;
a light-receiving unit installed on the substrate, the light-receiving unit converting an input optical signal into an electric signal;
at least one of an anode electrode pad electrically connected to an anode of the light-receiving unit;
at least one of a cathode electrode pad electrically connected to a cathode of the light-receiving unit; and
a ground pad provided on each of both sides of the anode electrode pad and the cathode electrode pad,
wherein a length of the ground pad in a longitudinal direction is twice or more a length of the ground pad in a width direction.

4. The photodetector according to claim 1, wherein the photodetector is any one of a back incident type photodiode, a front incident type photodiode, and an end surface incident type photodiode.

5. The photodetector according to claim 2, wherein the photodetector is any one of a back incident type photodiode, a front incident type photodiode, and an end surface incident type photodiode.

6. The photodetector according to claim 3, wherein the photodetector is any one of a back incident type photodiode, a front incident type photodiode, and an end surface incident type photodiode.
